(19) United States
(12) Patent Application Publication
(10) Pub. No.: US 2026/0215142 A1
(43) Pub. Date: Jul. 23, 2026

(54) DISPLAY PANEL AND DISPLAY DEVICE

(71) Applicant: TCL CHINA STAR OPTOELECTRONICS TECHNOLOGY CO., LTD., Shenzhen (CN)

(72) Inventor: Wei YUAN, Shenzhen (CN)

(73) Assignee: TCL CHINA STAR OPTOELECTRONICS TECHNOLOGY CO., LTD., Shenzhen (CN)

(21) Appl. No.: 19/093,055

(22) Filed: Mar. 27, 2025

(30) Foreign Application Priority Data
Jan. 17, 2025 (CN) 202510081813.6

(51) Int. Cl. H10K 59/88; H10K 59/35

(52) U.S. Cl. CPC H10K 59/88; H10K 59/353

(57) ABSTRACT

A display panel and a display device are provided by the present disclosure. The display panel includes a display region and a non-display region located at least one side of the display region. A non-display region is provided with a plurality of dummy pixels. The display region is provided with a plurality of sub-pixels arranged along a first direction and a second direction. The plurality of dummy pixels and corresponding ones of the plurality of sub-pixels are arranged side by side along the first direction. The plurality of dummy pixels include at least two types of outer contours in a top view of the display panel.

### CROSS-REFERENCE TO RELATED APPLICATION

This application claims priority to and the benefit of Chinese Patent Application No. 202510081813.6, filed on Jan. 17, 2025, the disclosure of which is incorporated herein by reference in its entirety.

### TECHNICAL FIELD

The present disclosure relates to the field of display technologies, and more particularly to a display panel and a display device.

### BACKGROUND

Organic light-emitting diodes (OLED) belong to a new type of current-type semiconductor light-emitting devices, which realize display by controlling carriers in the devices to excite organic materials to emit light.

For a current high-resolution OLED display panel, there is a large difference between a saturated vapor pressure of a solvent of sub-pixels in a peripheral region and a saturated vapor pressure of a solvent of sub-pixels in a central region of the display panel, resulting in a difference in a film thickness of a light-emitting layer of sub-pixels in the central region and a film thickness of a light-emitting layer of sub-pixels in the peripheral region. In order to solve the technical problem, at present, dummy pixels are arranged in a non-display region of the display panel, so that the sub-pixels with uneven thickness are arranged in the non-display region, and the film uniformity of the sub-pixels in the display region is ensured. However, a width of a frame of the display panel is increased due to the dummy pixels, which is contrary to a narrow frame design of the current display panel.

### SUMMARY

A display panel and a display device are provided by the present disclosure, so as to solve the technical problem that a width of a frame of the display panel is relatively large.

The present disclosure provides technical solutions as follows.

A display panel is provided by the present disclosure. The display panel includes a display region and a non-display region located on at least one side of the display region, where the non-display region is provided with a plurality of dummy pixels, and the display region is provided with a plurality of sub-pixels arranged along a first direction and a second direction.

The plurality of dummy pixels and corresponding ones of the plurality of sub-pixels are arranged side by side along the first direction, and the plurality of dummy pixels include at least two kinds of outer contours in a top view of the display panel.

A display device is further provided by the present disclosure. The display device includes the display panel as described above.

Other features and advantages of the present disclosure will be described in detail in the following detailed description.

### BRIEF DESCRIPTION OF THE DRAWINGS

To more clearly illustrate the technical solutions in the embodiments of the present application, the drawings used in the description of the embodiments will be briefly introduced. It is evident that the drawings described below are only some embodiments of the present application, and for those skilled in the art, other drawings can be obtained from these drawings without creative efforts.

In order to fully understand the present disclosure and beneficial effects thereof, the description will be given below in conjunction with the drawings, and the same reference numbers in the description below indicate the same parts in the drawings.

FIG. 1 is a schematic structural view of a display panel according to the embodiments of the present disclosure.

FIG. 2 is an enlarged view of a region M in FIG. 1.

FIG. 3 is a film layer view of a display panel according to the embodiments of the present disclosure.

### DETAILED DESCRIPTION

The technical solution in the embodiments of the present disclosure will be clearly and completely described with reference to the accompanying drawings. Apparently, the described embodiments are merely some embodiments of the present disclosure instead of all embodiments. According to the embodiments in the present disclosure, all other embodiments obtained by those skilled in the art without making any creative effort shall fall within of protection scope of the present disclosure.

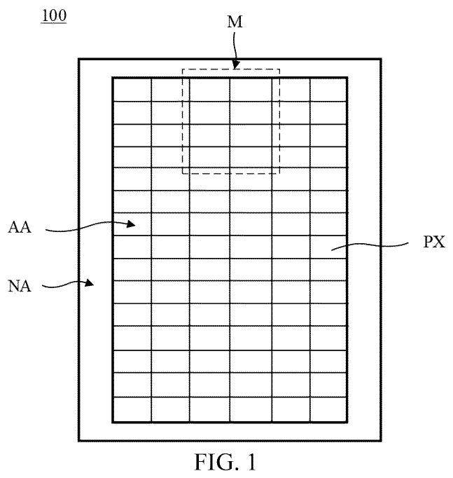

Referring to FIGS. 1 to 3, a display panel 100 is provided by the present disclosure. The display panel 100 includes a display region AA and a non-display region NA disposed on at least one side of the display region AA. The display region AA is provided with a plurality of sub-pixels PX arranged along a first direction X and a second direction Y.

In some embodiments, a dummy pixel portion 80 including a plurality of dummy pixels is disposed in the non-display region NA. The plurality of dummy pixels and corresponding ones of the sub-pixels PX are arranged side by side along the first direction X. The plurality of dummy pixels includes at least two types of outer contours in a plan view of the display panel 100.

In the present disclosure, by changing the outer contours of the dummy pixels in the non-display region NA, the dummy pixels in the non-display region NA have at least two types of outer contours. The types of the outer contours are increased, thereby improving the carrying capacity of ink, reducing a number of the dummy pixels, and reducing a width of a frame of the display panel 100.

In some embodiments, the plurality of sub-pixels PX located in the display region AA may include a plurality of first pixel groups PXL1 and a plurality of second pixel groups PXL2. Each of the plurality of first pixel groups PXL1 includes a plurality of first pixel units RU1 arranged along the first direction X. The plurality of second pixel groups PXL2 are arranged at intervals from the plurality of first pixel groups PXL1 along the second direction Y. Each of the second pixel groups PXL2 includes a plurality of second pixel units RU2 arranged along the first direction X.

In some embodiments, each of the first pixel units RU1 and the second pixel units RU2 includes at least three sub-pixels PX having different light-emitting colors and arranged along the second direction Y. An arrangement of the sub-pixels PX in each of the first pixel units RU1 is mirrored with an arrangement of the sub-pixels PX in each of the second pixel units RU2.

In some embodiments, in the second direction Y, a first retaining wall 30a is disposed between adjacent two of the sub-pixels PX having a same light-emitting color, and a second retaining wall 30b is disposed between adjacent two of the sub-pixels PX having different light-emitting colors. A thickness of the first retaining wall 30a is less than a thickness of the second retaining wall 30b.

As a resolution of the display panel 100 increases, an ink volume required by a single one of the sub-pixels PX and a pitch between adjacent two of the sub-pixels PX are both reduced. However, a minimum printing volume of a current printing device is greater than the ink volume required by the single one of the sub-pixels PX, and a minimum moving pitch of the printing device is greater than a pitch between the adjacent two of the sub-pixels PX, resulting in a mismatch between the printing accuracy of the current printing device and the current high-resolution display panel 100. In the present disclosure, the arrangements of the sub-pixels PX in adjacent two of the pixel units are mirrored with each other, and the retaining wall with a smaller thickness is disposed between the adjacent two of the sub-pixels PX having the same light-emitting color, so that the adjacent two of the sub-pixels PX having the same light-emitting color can be printed by a same drop of ink. Furthermore, a pitch between the adjacent two of the sub-pixels PX with different light-emitting colors is increased, so that the printing accuracy required by the high-resolution display panel 100 is reduced, and the printing accuracy of the current printing device is matched with the current high-resolution display panel 100, thereby reducing manufacturing costs.

It should be noted that in the present disclosure, each of the first pixel units RU1 and the second pixel units RU2 may include a first sub-pixel PX1, a second sub-pixel PX2, and a third sub-pixel PX3 arranged along the second direction Y and having different light-emitting colors. The light-emitting colors of the first sub-pixel PX1, the second sub-pixel PX2, and the third sub-pixel PX3 may be different from each other among red, green, and blue, respectively. In the following embodiments, the light-emitting color of the first sub-pixel PX1 being red, the light-emitting color of the second sub-pixel PX2 being blue, and the light-emitting color of the third sub-pixel PX3 being green will be described as an example.

The technical solution of the present disclosure is described in conjunction with specific embodiments.

Referring to FIG. 1, the display panel 100 includes the display region AA and the non-display region NA disposed adjacent to the display region AA. Optionally, the non-display region NA surrounds the display region AA, so that the display region AA is surrounded by the non-display region NA. The display region AA is a region of the display panel 100 for performing a display function. The display region AA is provided with a plurality of sub-pixels PX to realize the display function. The non-display region NA may be a frame region of the display panel 100. A functional component for assisting the sub-pixels PX in the display region AA to display may be disposed in the non-display region NA.

Referring to FIG. 1, bonding terminals may be disposed on a lower side of the display region AA. The bonding terminals may be connected to an external circuit. The bonding terminals transmit signals input from the external circuit to data lines, thereby driving the display panel 100 to display pictures. For example, the bonding terminals can be bonded to a chip or a flip-chip film, so as to provide power supply and driving signals for the display panel 100.

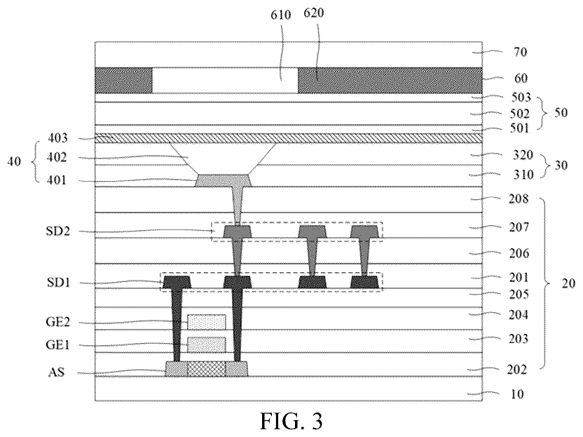

Referring to FIG. 3, the display panel 100 may include a substrate 10, an array layer 20 disposed on the substrate 10, a pixel layer 30 disposed on the array layer 20, a light-emitting functional layer 40, an encapsulation layer 50, a color filter layer 60 disposed on the encapsulation layer 50, and a cover layer 70 disposed on the color filter layer 60.

In some embodiments, a material of the substrate 10 may be a material such as glass, quartz, or polyimide. For example, under a case where the display panel 100 is a flexible panel, the material of the substrate 10 may be a flexible material such as polyimide, or may be composed of a laminated film layer of a flexible material and an inorganic material. Under a case where the display panel 100 is a rigid panel, the material of the substrate 10 may be a rigid material, such as glass or quartz.

In some embodiments, referring to FIG. 3, the pixel layer 30 may include a plurality of thin film transistors. Each of the thin film transistors may be an etching barrier type, a back-channel etching type, or may be divided into a bottom-gate type thin film transistor or a top gate type thin film transistor, etc., according to positions of a gate and an active layer, but is not limited. For example, the thin film transistor shown in FIG. 3 is the top gate type thin film transistor. The top gate type thin film transistor may include a light shielding layer, a buffer layer, an active layer AS, a first gate insulating layer 202, a first gate layer GE1, a second gate insulating layer 203, a second gate layer GE2, a first interlayer insulating layer 204, a second interlayer insulating layer 205, a first source/drain layer SD1, a third interlayer insulating layer 201, a first planarization layer 206, a second source/drain layer SD2, a second planarization layer 207, and a third planarization layer 208. The light shielding layer is disposed on the substrate 10. The buffer layer is disposed on the light shielding layer. The active layer AS is disposed on the buffer layer. The first gate insulating layer 202 is disposed on the active layer AS. The first gate layer GE1 is disposed on the first gate insulating layer 202. The second gate insulating layer 203 is disposed on the first gate layer GE1. The second gate layer GE2 is disposed on the second gate insulating layer 203. The first interlayer insulating layer 204 is disposed on the second gate layer GE2. The second interlayer insulating layer 205 is disposed on the first interlayer insulating layer 204. The first source/drain layer SD1 is disposed on the second interlayer insulating layer 205. The third interlayer insulating layer 201 is disposed on the first source/drain layer SD1. The first planarization layer 206 is disposed on the third interlayer insulating layer 201. The second source/drain layer SD2 is disposed on the first planarization layer 206. The second planarization layer 207 is disposed on the second source/drain layer SD2. The third planarization layer 208 is disposed on the second planarization layer 207.

It should be noted that a number of the source/drain layers may be set according to demands for wiring space. For example, the source/drain layers in the present disclosure may be two layers. Furthermore, a number of the gate layers is set according to the demands of wiring space and capacitance. For example, the gate layers in the present disclosure may be two layers.

It should be noted that the buffer layer, the first gate insulating layer 202, the second gate insulating layer 203, each of the first interlayer insulating layer 204, the second interlayer insulating layer 205, and the third interlayer insulating layer 201 may be made of an inorganic material composed of an element such as nitrogen, silicon, oxygen, and aluminum, e.g., a single layer or a plurality of stacked inorganic film layers composed of one of silicon nitride, silicon oxide, and aluminum oxide.

It should be noted that the planarization layers in the present disclosure are provided to ensure the flatness of the film layers. A number of the planarization layers is set according to demands of flatness, e.g., the planarization layers in the present disclosure may be three layers.

Referring to FIG. 3, the pixel layer 30 may include a first pixel definition layer 310 and a second pixel definition layer 320. The first pixel definition layer 310 is disposed on a side of the third planarization layer 208 away from the substrate 10. The second pixel definition layer 320 is disposed on a surface of the first pixel definition layer 310 on a side away from the substrate 10.

It should be noted that since the light-emitting layer 402 in the present disclosure is manufactured by an ink-jet printing process, in order to reduce the accuracy of the ink-jet printing process, the first pixel definition layer 310 in the present disclosure may include a plurality of third retaining walls 30c horizontally and vertically staggered. The third retaining walls 30c horizontally and vertically staggered enclose to form a plurality of pixel openings corresponding to the sub-pixels. The second pixel definition layer 320 includes a plurality of second retaining walls 30b horizontally or vertically staggered. The plurality of sub-pixels between adjacent two of the second retaining walls 30b have a same color. Thus during the ink-jet printing process, the plurality of sub-pixels between adjacent two of the second retaining walls 30b can be simultaneously printed along an arrangement direction of the second retaining walls 30b, thereby reducing the accuracy of ink-jet printing and improving the process efficiency.

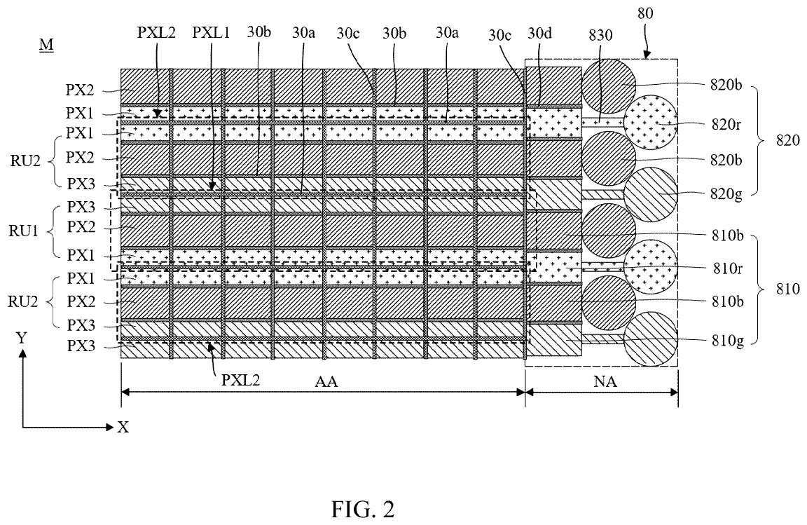

It should be noted that in the present disclosure, the first pixel definition layer 310 and the second pixel definition layer 320 may be formed during one process. That is, film layers of the first pixel definition layer 310 and the second pixel definition layer 320 are simultaneously formed, and the first pixel definition layer 310 and the second pixel definition layer 320 are patterned using a same photomask, so that the first pixel definition layer 310 forms the plurality of third retaining walls 30c, and the second pixel definition layer 320 forms the plurality of second retaining walls 30b. For example, in the present disclosure, the display panel 100 may include a plurality of third retaining walls 30c arranged along the first direction X and a plurality of second retaining walls 30b arranged along the second direction Y. Each of the third retaining walls 30c extends along the second direction Y, and each of the second retaining walls 30b extends along the first direction X. For details, please refer to FIG. 2 of the present disclosure.

It should be noted that the first retaining wall 30a in the present disclosure may also be manufactured during a process of patterning the first pixel definition layer 310, i.e., the thickness of the first retaining wall 30a may be equal to a thickness of the third retaining wall 30c.

In some embodiments, since the second retaining wall 30b mainly plays a role in isolating the sub-pixels having different colors, in the present disclosure, the thickness of the second retaining wall 30b may be greater than the thickness of the third retaining wall 30c.

It should be the display panel 100 further includes a support layer (not shown) disposed integrally with the pixel layer 30. The support layer is disposed on a surface of the second pixel definition layer 320 on a side away from the first pixel definition layer 310. The support layer and the pixel layer 30 may be formed during the same photomask process. The support layer may be used to support a mask.

It should be noted that a material of the pixel layer 30 and the support layer may be an organic positive photoresist.

Referring to FIG. 3, the light-emitting functional layer 40 may further include an anode layer 401 disposed on the third planarization layer 208, the light-emitting layer 402 disposed on the anode layer 401, and a cathode layer 403 disposed on the light-emitting layer 402. The anode layer 401 includes a plurality of anodes in a one-to-one correspondence with the plurality of pixel openings. The light-emitting layer 402 may include a plurality of light-emitting pixels in a one-to-one correspondence with the plurality of anodes.

Referring to FIG. 3, the encapsulation layer 50 covers the pixel layer 30 and continuously covers the plurality of pixel openings and the plurality of light-emitting pixels. The encapsulation layer 50 may include a first inorganic encapsulation layer 501, an organic encapsulation layer 502, and a second inorganic encapsulation layer 503 stacked in sequence.

Referring to FIG. 3, the color filter layer 60 includes a plurality of color resistors 610 and a plurality of light shielding units 620. Each of the light shielding units 620 is disposed between adjacent two of the color resistors 610. Each of the color resistors 610 corresponds to one of the light-emitting pixels.

Referring to FIG. 3, the cover plate layer 70 is disposed on a side of the color filter layer 60 away from the substrate 10. The cover plate layer 70 may be a glass cover plate or may be formed directly on the color filter layer 60.

Referring to FIG. 2, the arrangement of the sub-pixels PX in each of the first pixel units RU1 is mirrored with the arrangement of the sub-pixels PX in each of the second pixel units RU2. For example, in each of the first pixel units RU1, the first sub-pixel PX1, the second sub-pixel PX2, and the third sub-pixel PX3 are arranged along the second direction Y. In each of the second pixel units RU2, the third sub-pixel PX3, the second sub-pixel PX2, and the first sub-pixel PX1 are arranged along the second direction Y. As a result, the first sub-pixel PX1 in each of the first pixel units RU1 is adjacent to the first sub-pixel PX1 in an adjacent one of second pixel unit RU2, and the third sub-pixel PX3 in each of the first pixel units RU1 is adjacent to the third sub-pixel PX3 in another adjacent one of the second pixel units RU2.

In the structure of FIG. 2, since each of the plurality of first pixel groups PXL1 includes the plurality of first pixel units RU1 arranged along the first direction X, and each of the second pixel groups PXL2 includes the plurality of second pixel units RU2 arranged along the first direction X, the plurality of sub-pixels PX in the first direction X are all the sub-pixels PX having the same light-emitting color.

In the structure of FIG. 2, a second retaining wall 30b is disposed between two adjacent sub-pixels PX having different light-emitting colors, i.e., the second retaining wall 30b in the present disclosure is disposed between the first sub-pixel PX1 and the second sub-pixel PX2 and between the second sub-pixel PX2 and the third sub-pixel PX3. Furthermore, since the first retaining wall 30a is disposed between two adjacent sub-pixels PX having the same light-emitting color, i.e., the first retaining wall 30a in the present disclosure may extend along the first direction X, and the first retaining wall 30a is disposed between two adjacent first sub-pixels PX1 and between two adjacent third sub-pixels PX3.

In the structure of FIG. 2, for two adjacent rows of first sub-pixels PX1 or two adjacent rows of third sub-pixels PX3, the first retaining wall 30a is disposed between adjacent two of the first sub-pixels PX1 or adjacent two of the third sub-pixels PX3 in the second direction Y, the third retaining wall 30c is disposed between the adjacent two of the first sub-pixels PX1 or the adjacent two of the third sub-pixels PX3 in the first direction X, and the second retaining wall 30b is disposed between the two adjacent rows of the first sub-pixels PX1 or the two adjacent rows of the second sub-pixels PX2. Since the thickness of the second retaining wall 30b is greater than the thickness of the first retaining wall 30a and the thickness of the third retaining wall 30c, when the first sub-pixels PX1 and the third sub-pixels PX3 are printed, the adjacent two of the first sub-pixels PX1 or the adjacent two of the third sub-pixels PX3 can be printed simultaneously. That is, times of printing the first sub-pixels PX1 and the third sub-pixels PX3 are effectively reduced, thereby improving the printing efficiency. Meanwhile, the adjacent two of the first sub-pixels PX1 or the adjacent two of the third sub-pixels PX3 can be printed simultaneously, so that a minimum ink volume required for the sub-pixels PX is increased and a printing spacing of adjacent sub-pixels PX in the second direction Y is improved. Thus the printing precision required for the high-resolution display panel 100 is reduced, which ensures that the printing precision of the current printing device matches requirements of the high-resolution display panel 100.

In some embodiments, in order to ensure the uniformity for printing the two adjacent rows of the first sub-pixels PX1 or the two adjacent rows of the third sub-pixels PX3, in the present disclosure, the thickness of the third retaining wall 30c may be less than or equal to the thickness of the first retaining wall 30a, e.g., the thickness of the third retaining wall 30c may be equal to the thickness of the first retaining wall 30a.

In some embodiments, since the light-emitting color of the second sub-pixel PX2 is blue, and a light-emitting efficiency of the blue sub-pixel is lower than a light-emitting efficiency of the red sub-pixel and a light-emitting efficiency of the green sub-pixel, in the present disclosure, an area of the second sub-pixel PX2 can be increased. For example, the area of the second sub-pixel PX2 is greater than an area of the first sub-pixel PX1, and the area of the second sub-pixel PX2 is greater than an area of the third sub-pixel PX3, so that the light-emitting efficiency of the first sub-pixel PX1 and the light-emitting efficiency of the third sub-pixel PX3 can be close to each other, and the display uniformity of the display panel 100 can be improved.

Referring to FIG. 2, the dummy pixel portion 80 may include a plurality of first shape pixels 810 and a plurality of second shape pixels 820. For example, in the present disclosure, an outer contour of each of the first shape pixels 810 is rectangular, and an outer contour of each of the second shape pixels 820 is polygonal or circular.

For example, in the structure of FIG. 2, the present disclosure is described by taking the outer contour of each of the first shape pixels 810 being rectangular and the outer contour of each of the second shape pixels 820 being circular as an example. In the present disclosure, the plurality of first shape pixels 810 are arranged side by side along the second direction Y, and the plurality of second shape pixels 820 are arranged staggered along the second direction Y. The plurality of first shape pixels 810 may be arranged adjacent to the display region AA, and the plurality of second shape pixels 820 may be arranged on a side of the plurality of first shape pixels 810 away from the display region AA.

In some embodiments, a first one of the first shape pixels 810 is disposed adjacent to two first sub-pixels PX1, a second one of the first shape pixels 810 is disposed adjacent to one second sub-pixel PX2, and a third one of the first shape pixels 810 is disposed adjacent to two third sub-pixels PX3. For example, the plurality of first shape pixels 810 may include a first red pixel 810r, a first blue pixel 810b, and a first green pixel 810g. The first green pixel 810g, the first blue pixel 810b, and the first red pixel 810r are arranged along the second direction Y. The first red pixel 810g may be disposed adjacent to the two first sub-pixels PX1. The first blue pixel 810b may be disposed adjacent to one second sub-pixel PX2. The first green pixel 810g may be disposed adjacent to the two third sub-pixels PX3.

Referring to FIG. 2, the plurality of first shape pixels 810 are disposed adjacent to the sub-pixels PX in the display region AA. In order to allow the ink in the sub-pixels PX in the display region AA to enter the corresponding first shape pixels 810, in the present disclosure, the third retaining walls 30c may be disposed between the first shape pixels 810 and the sub-pixels PX in the adjacent display region AA.

Furthermore, an area of each of the first shape pixels 810 may be equal or partially equal. For example, an area of the first blue pixel 810b may be equal to an area of the second sub-pixel PX2, the area of the first red pixel 810r may be equal to an area of the two first sub-pixels PX1, and an area of the first green pixel 810g may be equal to an area of the two third sub-pixels PX3. Alternatively, the area of the first red pixel 810r, the area of the first blue pixel 810b, and the area of the first green pixel 810g are all equal.

Referring to FIG. 2, some of the plurality of second shape pixels 820 corresponding to a plurality of second sub-pixels PX2 are arranged close to the display region AA, and another some of the plurality of second shape pixels 820 corresponding to the plurality of first sub-pixels PX1 and the plurality of third sub-pixels PX2 are arranged away from the display region AA.

For example, the plurality of second shape pixels 820 may include a plurality of second red pixels 820r, a plurality of second blue pixels 820b, and a plurality of second green pixels 820g. The plurality of second blue pixels 820b may be disposed close to the display region AA. The plurality of second red pixels 820r and the plurality of second green pixels 820g may be disposed away from the display region AA. Furthermore, the plurality of second blue pixels 820b are arranged at intervals along the second direction Y, and the plurality of second red pixels 820r and the plurality of second green pixels 820g may be arranged at intervals along the second direction Y.

In some embodiments, the dummy pixel portion 80 may further include a plurality of connection segments 830. Each of the connection segments 830 is disposed between adjacent two of the second shape pixels 810 corresponding to the second sub-pixels PX2. Two ends of each of the connection segments 830 are respectively connected to a corresponding one of the first shape pixels 810 and a corresponding one of second shape pixels 820 corresponding to the two first sub-pixels PX1 or the two third sub-pixels PX2.

For example, in the structure of FIG. 2, since a pitch between adjacent two of the second blue pixels 820b in the second direction Y is too small, the second red pixel 820r or the second green pixel 820g cannot be disposed between the adjacent two of the second blue pixels 820b. Thus in the present disclosure, the second red pixel 820r may be connected to the first red pixel 810r through one of the connection segments 830, the second green pixel 820g may be connected to the first green pixel 810g through another one of the connection segments 830, so that the ink from each of the first shape pixels 810 flows into the corresponding one of the second shape pixels 820.

It should be noted that, in order to facilitate the flow of ink, a corresponding retaining wall structure is not provided between the first shape pixel 810 and the second shape pixel 820, i.e., the first shape pixel 810 and the second shape pixel 820 are communicated with each other.

It should be noted that since the outer contour of the second shape pixel 820 of the present disclosure is circular, the carrying capacity of the ink of a circular structure is greatly increased compared with the dummy pixel with a square structure in the prior art, and the circular structure does not need to add additional dummy pixels, thereby reducing a number of dummy pixels. For example, eight dummy pixels are generally disposed in the display region AA in the prior art, while the first shape pixel 810 and the second shape pixel 820 of the present disclosure only occupy a width of original three dummy pixels, thereby reducing the width of the frame occupied by the dummy pixels, and realizing the narrow frame design of the display panel 100.

It should be noted that since the ink of the present disclosure only flows along the first direction X, the dummy pixels of the present disclosure are provided only on both sides of the display region AA in the first direction X.

It should be noted that the display region AA is similarly provided with related dummy pixels on both sides of the second direction Y, but the dummy pixels in the second direction Y are not used to carry excess ink in the display region AA.

In some embodiments, in order to avoid interference between the ink with different colors, in the present disclosure, a fourth retaining wall 30d may be disposed between adjacent two of the first shape pixel 810 in the second direction Y, and a thickness of the fourth retaining wall 30d is the same as the thickness of the second retaining wall 30b. For example, the fourth retaining wall 30d may be disposed between adjacent two of the first shape pixels 810.

A display device is provided by the present disclosure. The display device includes the display panel mentioned above. It should be noted that the device in the present disclosure can be any product or component with a display function, such as mobile phones, tablets, televisions, monitors, laptops, digital photo frames, navigation systems, etc.

In the description of the present disclosure, it is to be understood that the terms “first”, “second” and the like are used for descriptive purposes only and are not to be construed as indicating or implying relative importance or implying an amount of indicated technical features. Thus, features defined with “first” and “second” may explicitly or implicitly include one or more of the feature. In the disclosure, the term “plurality” means two or more than two, unless explicitly defined otherwise.

In the above-mentioned embodiments, the description of each embodiment has its own emphasis, and parts not described in detail in a certain embodiment may be referred to the related description of other embodiments.

The embodiments, implementations and related technical features of the present disclosure can be combined and replaced with each other without conflict.

The above embodiments are merely preferred embodiments of the present disclosure, and do not limit the present disclosure in any form. Any simple modifications, equivalent changes, and modifications made to the above embodiments according to the technical essence of the present disclosure without departing from the content of the technical proposal of the present disclosure still fall within the scope of the technical proposal of the present disclosure.

What is claimed is:

1. A display panel comprising a display region and a non-display region located on at least one side of the display region, wherein the non-display region is provided with a plurality of dummy pixels, and the display region is provided with a plurality of sub-pixels arranged along a first direction and a second direction;
wherein the plurality of dummy pixels and corresponding ones of the plurality of sub-pixels are arranged side by side along the first direction, and the plurality of dummy pixels comprise at least two kinds of outer contours in a top view of the display panel.

2. The display panel according to claim 1, wherein the plurality of sub-pixels comprise:
a plurality of first pixel groups comprising a plurality of first pixel units arranged along the first direction;
a plurality of second pixel groups arranged along the second direction at intervals from the plurality of first pixel groups, wherein each of the plurality of second pixel groups comprises a plurality of second pixel units arranged along the first direction, each of the plurality of first pixel units and the plurality of second pixel units comprises at least three of the plurality of sub-pixels having different light-emitting colors and arranged along the second direction, and an arrangement of the sub-pixels in each of the plurality of first pixel units is mirrored with an arrangement of the sub-pixels in each of the plurality of second pixel units; and
wherein in the second direction, a first retaining wall is disposed between adjacent two of the sub-pixels having a same light-emitting color, a second retaining wall is disposed between adjacent two of the sub-pixels having different light-emitting colors, and a thickness of the first retaining wall is less than a thickness of the second retaining wall.

3. The display panel according to claim 2, wherein each of the plurality of first pixel units and the plurality of second pixel units comprises a first sub-pixel, a second sub-pixel, and a third sub-pixel arranged along the second direction; and
wherein the first sub-pixel in each of the plurality of first pixel units is disposed adjacent to the first sub-pixel in an adjacent one of the plurality of second pixel units, and the third sub-pixel of each of the plurality of first pixel units is disposed adjacent to the third sub-pixel in another adjacent one of the plurality of second pixel units.

4. The display panel according to claim 3, wherein an area of the second sub-pixel is greater than an area of the first sub-pixel, and an area of the second sub-pixel is greater than an area of the third sub-pixel.

5. The display panel according to claim 3, wherein adjacent two of the sub-pixels arranged along the first direction have a same light-emitting color, a third retaining wall is disposed between the adjacent two of the sub-pixels having the same light-emitting color, and a thickness of the third retaining wall is less than or equal to the thickness of the first retaining wall.

6. The display panel according to claim 3, wherein the plurality of dummy pixels comprise a plurality of first shape pixels arranged adjacent to the display region, and the plurality of first shape pixels are arranged side by side along the second direction; and
wherein a first one of the plurality of first shape pixels is disposed adjacent to two first sub-pixels, a second one of the plurality of first shape pixels is disposed adjacent to one second sub-pixel, and a third one of the plurality of first shape pixels is disposed adjacent to two third sub-pixels.

7. The display panel according to claim 6, wherein the plurality of dummy pixels comprise a plurality of second shape pixels arranged on a side of the plurality of first shape pixels away from the display region, and the plurality of second shape pixels are arranged in a staggered manner along the second direction; and
wherein some of the plurality of second shape pixels corresponding to a plurality of second sub-pixels are arranged close to the display region, and another some of the plurality of second shape pixels corresponding to the plurality of first sub-pixels and the plurality of third sub-pixels are arranged away from the display region.

8. The display panel according to claim 7, wherein the non-display region is further provided with a plurality of connection segments, each of the connection segments is disposed between adjacent two of the plurality of second shape pixels corresponding to the second sub-pixels, and two ends of each of the connection segments are respectively connected to a corresponding one of the plurality of first shape pixels and a corresponding one of the plurality of second shape pixels corresponding to the two first sub-pixels or the two third sub-pixels.

9. The display panel according to claim 7, wherein an outer contour of each of the plurality of first shape pixels is rectangular, and an outer contour of each of the plurality of second shape pixels is circular.

10. The display panel according to claim 2, wherein a fourth retaining wall is disposed between adjacent two of the plurality of dummy pixels in the second direction, and a thickness of the fourth retaining wall is the same as the thickness of the second retaining wall.

11. The display panel according to claim 3, wherein a light-emitting color of the first sub-pixel is red, a light-emitting color of the second sub-pixel is blue, and a light-emitting of the third sub-pixel is green.

12. A display device, comprising a display panel, wherein the display panel comprises a display region and a non-display region located on at least one side of the display region, the non-display region is provided with a plurality of dummy pixels, and the display region is provided with a plurality of sub-pixels arranged along a first direction and a second direction; and
wherein the plurality of dummy pixels and corresponding ones of the plurality of sub-pixels are arranged side by side along the first direction, and the plurality of dummy pixels comprise at least two kinds of outer contours in a top view of the display panel.

13. The display device according to claim 12, wherein the plurality of sub-pixels comprise:
a plurality of first pixel groups comprising a plurality of first pixel units arranged along the first direction;
a plurality of second pixel groups arranged along the second direction at intervals from the plurality of first pixel groups, wherein each of the plurality of second pixel groups comprises a plurality of second pixel units arranged along the first direction, each of the plurality of first pixel units and the plurality of second pixel units comprises at least three of the plurality of sub-pixels having different light-emitting colors and arranged along the second direction, and an arrangement of the sub-pixels in each of the plurality of first pixel units is mirrored with an arrangement of the sub-pixels in each of the plurality of second pixel units; and
wherein in the second direction, a first retaining wall is disposed between adjacent two of the sub-pixels having a same light-emitting color, a second retaining wall is disposed between adjacent two of the sub-pixels having different light-emitting colors, and a thickness of the first retaining wall is less than a thickness of the second retaining wall.

14. The display device according to claim 13, wherein each of the plurality of first pixel units and the plurality of second pixel units comprises a first sub-pixel, a second sub-pixel, and a third sub-pixel arranged along the second direction; and
wherein the first sub-pixel in each of the plurality of first pixel units is disposed adjacent to the first sub-pixel in an adjacent one of the plurality of second pixel units, and the third sub-pixel of each of the plurality of first pixel units is disposed adjacent to the third sub-pixel in another adjacent one of the plurality of second pixel units.

15. The display device according to claim 14, wherein an area of the second sub-pixel is greater than an area of the first sub-pixel, and an area of the second sub-pixel is greater than an area of the third sub-pixel.

16. The display device according to claim 14, wherein adjacent two of the sub-pixels arranged along the first direction have a same light-emitting color, a third retaining wall is disposed between the adjacent two of the sub-pixels having the same light-emitting color, and a thickness of the third retaining wall is less than or equal to the thickness of the first retaining wall.

17. The display device according to claim 14, wherein the plurality of dummy pixels comprise a plurality of first shape pixels arranged adjacent to the display region, and the plurality of first shape pixels are arranged side by side along the second direction; and
wherein a first one of the plurality of first shape pixels is disposed adjacent to two first sub-pixels, a second one of the plurality of first shape pixels is disposed adjacent to one second sub-pixel, and a third one of the plurality of first shape pixels is disposed adjacent to two third sub-pixels.

18. The display device according to claim 17, wherein the plurality of dummy pixels comprise a plurality of second shape pixels arranged on a side of the plurality of first shape pixels away from the display region, and the plurality of second shape pixels are arranged in a staggered manner along the second direction; and
wherein some of the plurality of second shape pixels corresponding to a plurality of second sub-pixels are arranged close to the display region, and another some of the plurality of second shape pixels corresponding to the plurality of first sub-pixels and the plurality of third sub-pixels are arranged away from the display region.

19. The display device according to claim 18, wherein the non-display region is further provided with a plurality of connection segments, each of the connection segments is disposed between adjacent two of the plurality of second shape pixels corresponding to the second sub-pixels, and two ends of each of the connection segments are respectively connected to a corresponding one of the plurality of first shape pixels and a corresponding one of the plurality of second shape pixels corresponding to the two first sub-pixels or the two third sub-pixels.

20. The display device according to claim 18, wherein an outer contour of each of the plurality of first shape pixels is rectangular, and an outer contour of each of the plurality of second shape pixels is circular.
